(19) United States
(12) Patent Application Publication
(10) Pub. No.: US 2026/0094645 A1
(43) Pub. Date: Apr. 2, 2026

(54) MEMORY-BASED NEURAL NETWORK DEVICE AND OPERATING METHOD THEREOF

(71) Applicant: Samsung Electronics Co., Ltd., Suwon-si (KR)

(72) Inventors: JEON IL LEE, Suwon-Si (KR); Youngin GOH, Suwon-Si (KR)

(21) Appl. No.: 19/240,492

(22) Filed: Jun. 17, 2025

(30) Foreign Application Priority Data
Oct. 2, 2024 (KR) 10-2024-0133918

(51) Int. Cl. G11C 11/54; G11C 11/22

(52) U.S. Cl. CPC G11C 11/54; G11C 11/221; G11C 11/2273; G11C 11/2275

(57) ABSTRACT

A neural network device includes a first memory cell connected to a first word line, a first bit line, and a first plate line, and a controller that provides a first plate voltage to the first memory cell through the first plate line. The first memory cell includes a transistor controlled by the first word line and connected to the first bit line, and a first ferroelectric capacitor set including a plurality of ferroelectric capacitors connected in parallel between the transistor and the first plate line.

### CROSS-REFERENCE TO RELATED APPLICATIONS

This application claims priority under 35 U.S.C. § 119 to Korean Patent Application No. 10-2024-0133918 filed on Oct. 2, 2024, in the Korean Intellectual Property Office, the disclosure of which is incorporated by reference herein in its entirety.

### BACKGROUND

Embodiments of the present disclosure described herein relate to a neural network device, and more particularly, relate to a memory-based neural network device and an operating method thereof.

Neuromorphic devices capable of implementing a neural network similar to a biological neural network are attracting attention. Neural networks are being used in various fields such as machine learning, selection, inference, prediction, recognition, analysis, translation, and diagnosis. A neural network may include artificial neurons that are similar to a neuron being a neural cell and which form a plurality of layers. A synapse weight may indicate connection strength between artificial neurons and may be learned and changed through the machine learning.

Nowadays, as the number of layers of the neural network and the number of artificial neurons increase, synapse weights and biases indicating connection strengths between artificial neurons are increasing in number. In the case of implementing a neural network at a semiconductor chip in the form of hardware, technologies for high integration and low power are typically required to store the synapse weights and biases increasing in number and to implement a plurality of artificial neurons.

### SUMMARY

Embodiments of the present disclosure provide a memory-based neural network device and an operating method thereof.

According to an embodiment, a neural network device includes a first memory cell connected to a first word line, a first bit line, and a first plate line, and a controller that provides a first plate voltage to the first memory cell through the first plate line. The first memory cell includes a transistor controlled by the first word line and connected to the first bit line, and a first ferroelectric capacitor set including a plurality of ferroelectric capacitors connected in parallel between the transistor and the first plate line.

According to an embodiment, a method of operating a neural network device including a controller and a memory device includes simultaneously providing, by the controller, a first plate voltage to ferroelectric capacitor sets of the memory device, the ferroelectric capacitor sets including a plurality of ferroelectric capacitors connected to a first plate line and configured to respectively store weights of a first layer, generating, by the memory device, read data by sensing a voltage of bit lines connected to the ferroelectric capacitor sets, providing, by the memory device, the read data to the controller, generating, by the controller, accumulation signals by accumulating the read data, generating, by the controller, activation signals by performing activation function calculations of the accumulation signals, determining, by the controller, whether the first layer is a last layer of a neural network, generating, by the controller, a second plate voltage based on the activation signals in response to determining that the first layer is not the last layer, and simultaneously providing, by the controller, the second plate voltage to the ferroelectric capacitor sets of the memory device.

### BRIEF DESCRIPTION OF THE FIGURES

The above and other objects and features of the present disclosure will become apparent by describing in detail embodiments thereof with reference to the accompanying drawings.

FIG. 1 is a block diagram of an electronic system, according to an embodiment of the present disclosure.

FIG. 2 is a diagram for describing a neural network operation, according to an embodiment of the present disclosure.

FIG. 3 is a block diagram of a neural network device, according to an embodiment of the present disclosure.

FIG. 4 is a block diagram of a memory cell, according to an embodiment of the present disclosure.

FIG. 5 is a circuit diagram for describing a conventional memory cell.

FIG. 6A is a circuit diagram for describing a memory cell, according to some embodiments of the present disclosure.

FIG. 6B is a circuit diagram for describing a memory cell, according to some embodiments of the present disclosure.

FIG. 7A is a graph for describing a level of a weight, according to some embodiments of the present disclosure.

FIG. 7B is a graph for describing a level of a weight, according to some embodiments of the present disclosure.

FIG. 8 is a diagram for describing a memory cell array, according to some embodiments of the present disclosure.

FIG. 9A is a block diagram of a neural network device, according to some embodiments of the present disclosure.

FIG. 9B is a block diagram of a neural network device, according to some embodiments of the present disclosure.

FIG. 10 is a block diagram of a neural network device, according to some embodiments of the present disclosure.

FIG. 11 is a flowchart for describing a method of operating a neural network device, according to some embodiments of the present disclosure.

FIG. 12 is a flowchart for describing a method of operating a neural network device, according to some embodiments of the present disclosure.

FIG. 13A is a perspective view for describing a plate line, according to some embodiments of the present disclosure.

FIG. 13B is a perspective view for describing a plate line, according to some embodiments of the present disclosure.

### DETAILED DESCRIPTION

Hereinafter, embodiments of the present disclosure will be described in detail and clearly to such an extent that one skilled in the art easily carries out the present disclosure.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

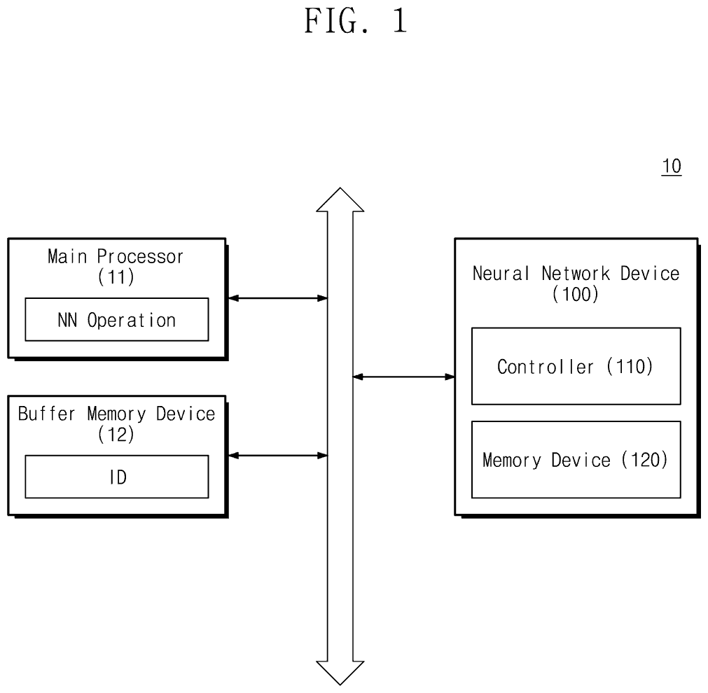

FIG. 1 is a block diagram of an electronic system, according to an embodiment of the present disclosure. Referring to FIG. 1, an electronic system 10 may be a computing system configured to process various pieces of information or to store the processed information as data. In some embodiments, the electronic system 10 may be a personal computer (PC), a notebook, a laptop, a server, a workstation, a tablet PC, a smartphone, a digital camera, or a black box.

The electronic system 10 may include a main processor 11, a buffer memory device 12, and a neural network device 100. The main processor 11 may control overall operations of the electronic system 10. In more detail, the main processor 11 may control operations of other components constituting the electronic system 10. The main processor 11 may be implemented with a general-purpose processor, a special-purpose processor, or an application processor, for example.

The main processor 11 may store data in the buffer memory device 12, may read out data stored in the buffer memory device 12, and may delete data stored in the buffer memory device 12.

The main processor 11 may perform a neural network operation or may provide data for performing the neural network operation to the neural network device 100. For example, the main processor 11 may read out input data ID stored in the buffer memory device 12, and may generate output data by performing a neural network operation on the input data ID, or may provide the input data ID to the neural network device 100.

The main processor 11 may communicate with the neural network device 100. For example, the main processor 11 may provide the input data ID to the neural network device 100, and may receive output data, which is the result obtained by performing the neural network operation of the input data ID, from the neural network device 100.

The buffer memory device 12 may be used as a main memory device of the electronic system 10, and may include a volatile memory such as an SRAM and/or a DRAM, or may include a non-volatile memory such as a flash memory, a PRAM, and/or an RRAM. The buffer memory device 12 may be implemented within the same package as the main processor 11. For example, the buffer memory device 12 and the main processor 11 may be part of a single semiconductor package, which may include a plurality of semiconductor chips stacked on a package substrate, or may be a package-on-package device. A first set of one or more semiconductor chips may form the buffer memory device 12 (e.g., as only a single chip or set of stacked chips, or as part of a first package including a package substrate and one or more semiconductor chips), and the second set of one or more semiconductor chips may form the main processor 11 (e.g., as only a single chip or set of stacked chips, or as part of a second package including a package substrate and one or more semiconductor chips).

The buffer memory device 12 may store data, may provide the stored data to the main processor 11, or may delete the stored data, depending on a request received from the main processor 11. For example, the buffer memory device 12 may store the input data ID, may provide the stored input data ID to the main processor 11, or may delete the stored input data ID, depending on a request received from the main processor 11.

In some embodiments, the buffer memory device 12 may store the input data ID, may provide the stored input data ID to the neural network device 100, or may delete the stored input data ID, depending on a request received from the main processor 11 or the neural network device 100.

The neural network device 100 may be a neuromorphic memory device, a neuromorphic computing device, a neuromorphic chip, a neuromorphic processor, a neuromorphic system, a neural network accelerator, a neural network accelerator chip, an artificial intelligence (AI) processor, an AI memory device, a processor, or a memory device. The neural network device 100 may be a memory-based neuromorphic device using the architecture of a memory device that stores data. For example, the neural network device 100 may be a memory-based neuromorphic device that utilizes the architecture of a memory device to store weight data for a neural network operation, such that, for example, each memory cell stores a particular weight value or indication.

The neural network device 100 may perform a neural network operation. For example, the neural network device 100 may perform a neural network operation based on the input data ID, and may return output data to the main processor 11. In some embodiments, the neural network device 100 may receive an input data ID from the main processor 11, the buffer memory device 12, or an external device, may perform the neural network operation based on the received input data ID, and may return an output value, which is the result of the neural network operation, to the main processor 11 or the external device.

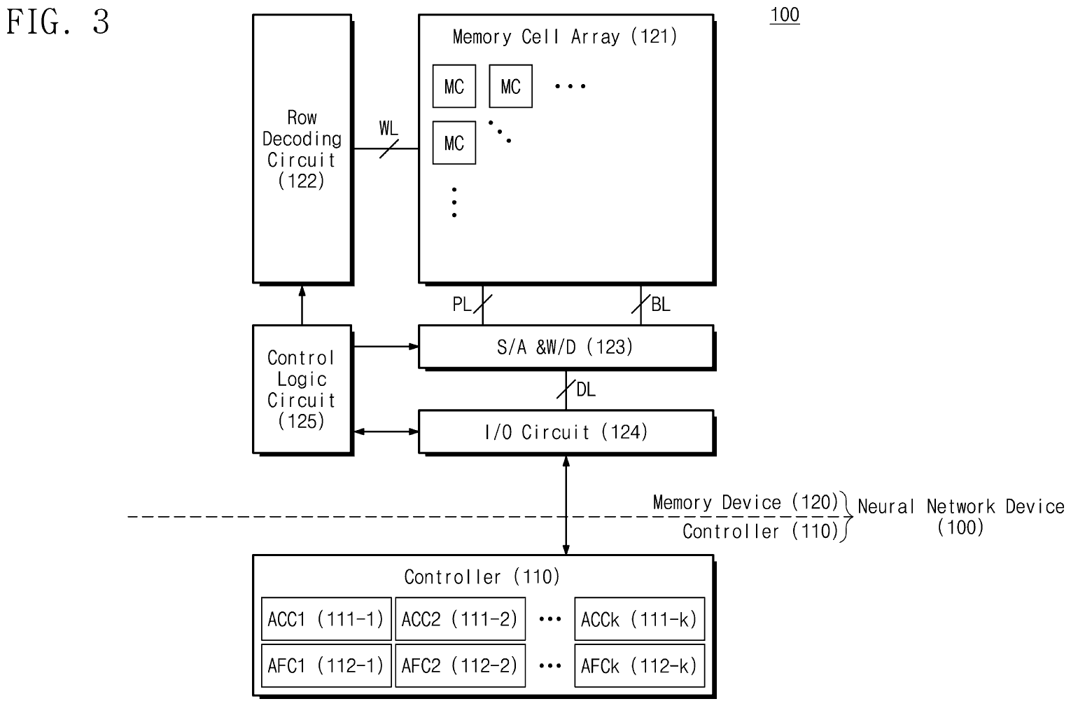

A more detailed description of the neural network device 100 will be described later with reference to FIG. 3.

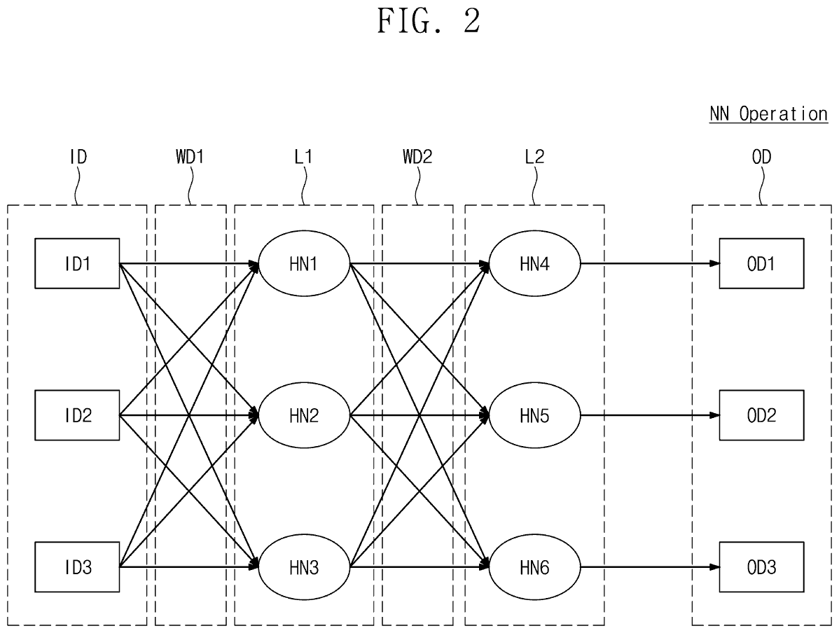

FIG. 2 is a diagram for describing a neural network operation, according to an embodiment of the present disclosure. Referring to FIG. 2, a neural network operation may include the input data ID, a first weight data WD1, a first layer L1, a second weight data WD2, a second layer L2, and an output data OD. The neural network operation is described to aid understanding of the present disclosure and is not intended to limit the scope of the present disclosure. The neural network operation may include input data, layers, nodes of layers, and output data, each of which the number is different from that described above.

The neural network operation may be an operation of processing the input data ID input into the neural network and generating the output data OD. For example, the neural network operation may be an operation of inputting the input data ID to a neural network and generating the output data OD (corresponding to the output value in FIG. 1) based on data passing through at least one or more layers (e.g., the first and second layers L1 and L2).

The neural network may include various derivative implementations, such as an artificial neural network (ANN), a convolutional neural network (CNN), a binarized neural network (BNN), a deep neural network (DNN), and a recursive neural network (RNN).

The input data ID may be data input into a neural network for learning or inference. The input data ID may be delivered to the first layer (or first hidden layer) L1 through the illustrated branches (or synapses). Each of the branches (or synapses) may be specified to have a corresponding weight (or the value of a synapse). The respective input data ID (e.g., first to third input data ID1 to ID3) may be calculated (e.g., multiplied) with the corresponding weight (or the value of a synapse) and may be delivered to the first layer L1.

The first weight data WD1 may include weights calculated together with the input data ID for being delivered to the first layer L1. For example, the first weight data WD1 may include weights of the branches connected to first to third hidden nodes HN1 to HN3 of the first layer L1 into which the first to third input data ID1 to ID3 are entered.

An accumulation operation may be performed on values input to nodes (e.g., the first to third hidden nodes HN1 to HN3) of the first layer L1. For example, an accumulation operation of the result of multiplying the first input data ID1, which is input to the first hidden node HN1, by the corresponding weight of the branch between first input data ID1 and the first hidden node HN1, the result of multiplying the second input data ID2, which is input to the first hidden node HN1, by the corresponding weight of the branch between second input data ID2 and the first hidden node HN1, and the result of multiplying the third input data ID3, which is input to the first hidden node HN1, by the corresponding weight of the branch between third input data ID3 and the first hidden node HN1 may be performed to generate a first accumulation value.

The activation function calculation may be performed on accumulation values (e.g., each of the first to third accumulation values) of each of the nodes (e.g., the first to third hidden nodes HN1 to HN3) of the first layer L1. The activation function may be at least one of a sigmoid function, a tangent hyperbolic (tanh) function, a rectified linear unit (ReLU) function, a leaky ReLU function, an exponential linear unit (ELU) function, a softmax function, a Swish function, and a Gaussian error linear unit (GELU) function. The results of performing the activation function calculation on the accumulation values (e.g., first to third accumulation values) of the nodes (e.g., the first to third hidden nodes HN1 to HN3) of the first layer L1 may be referred to as “activation values (or activation signals)” (e.g., first to third activation values or first to third activation signals).

The activation values of the nodes of the first layer L1 may be used with weights (or synapse values) of the second weight data WD2 (e.g., by multiplying each activation value by a weight), and the resulting data may be delivered to fourth to sixth hidden nodes HN4 to HN6 of the second layer (or the second hidden layer) L2. Inputs (similarly to inputs of the first to third hidden nodes HN1 to HN3) of the fourth to sixth hidden nodes HN4 to HN6 may be calculated with weights (or synapse values) of the second weight data WD2 and accumulated, and then an activation function calculation may be performed to output the output data OD (or an output signal) (e.g., first to third output data OD1 to OD3 or first to third output signals).

The respective output data OD (e.g., the first to third output data OD1 to OD3) may indicate the result of learning or inference of the respective input data ID (e.g., the first to third input data ID1 to ID3). In the example of FIG. 2, there are three input data and three output data, but the embodiments are not limited as such, and the number of input data (e.g., input data values, or input data pieces) may be different from the number of output data (e.g., output data values, or output data pieces).

FIG. 3 is a block diagram of a neural network device, according to an embodiment of the present disclosure. Referring to FIG. 3, the neural network device 100 may perform a neural network operation. For example, the neural network device 100 may receive input data from the main processor 11 of FIG. 1, the buffer memory device 12 of FIG. 1, or an external device, may perform the neural network operation based on the received input data, and may return output data, which is the result of the neural network operation, to the main processor 11 of FIG. 1 or the external device.

The neural network device 100 may include a controller 110 and a memory device 120. The controller 110 may control the memory device 120. For example, under the control of the controller 110, data (e.g., weights) may be stored in the memory device 120, or data (e.g., input data or activation signals) may be provided to the memory device 120, and some of the neural network operations (e.g., multiplication calculations of input data or activation signals, and weights) may be performed.

The controller 110 may communicate with the memory device 120. For example, the controller 110 may provide an address and data (e.g., weights, input data, or activation signals) to the memory device 120. In some embodiments, the controller 110 may provide input data to the memory device 120, and the input data (in a form of a voltage level) may be provided to memory cells MC via plate lines PL.

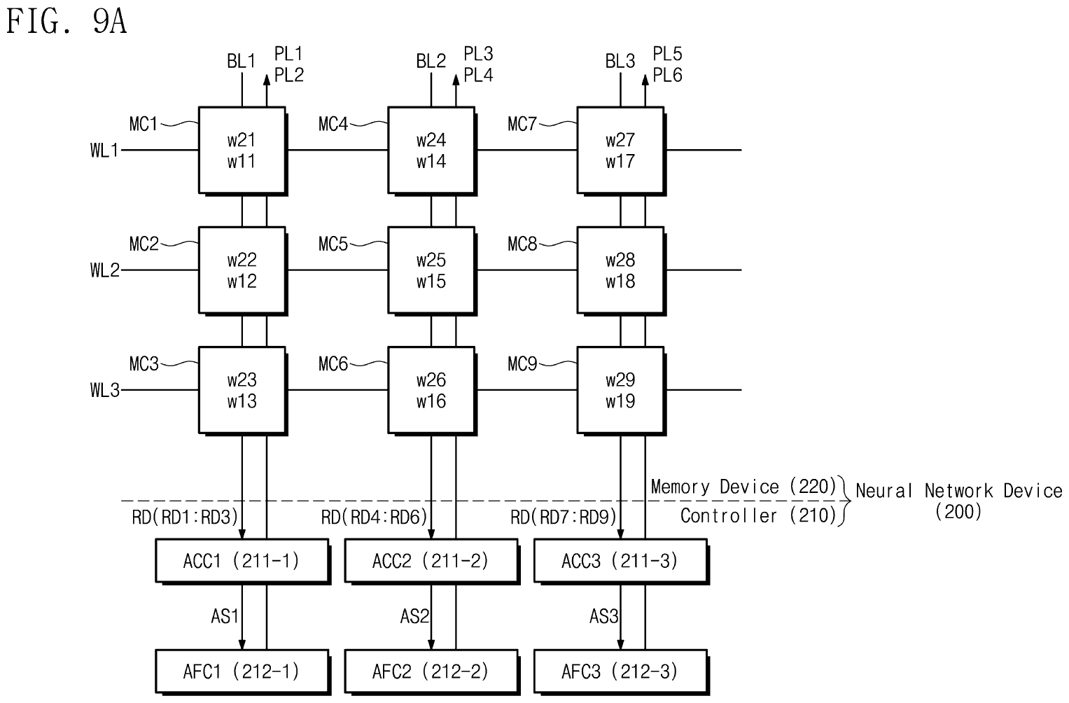

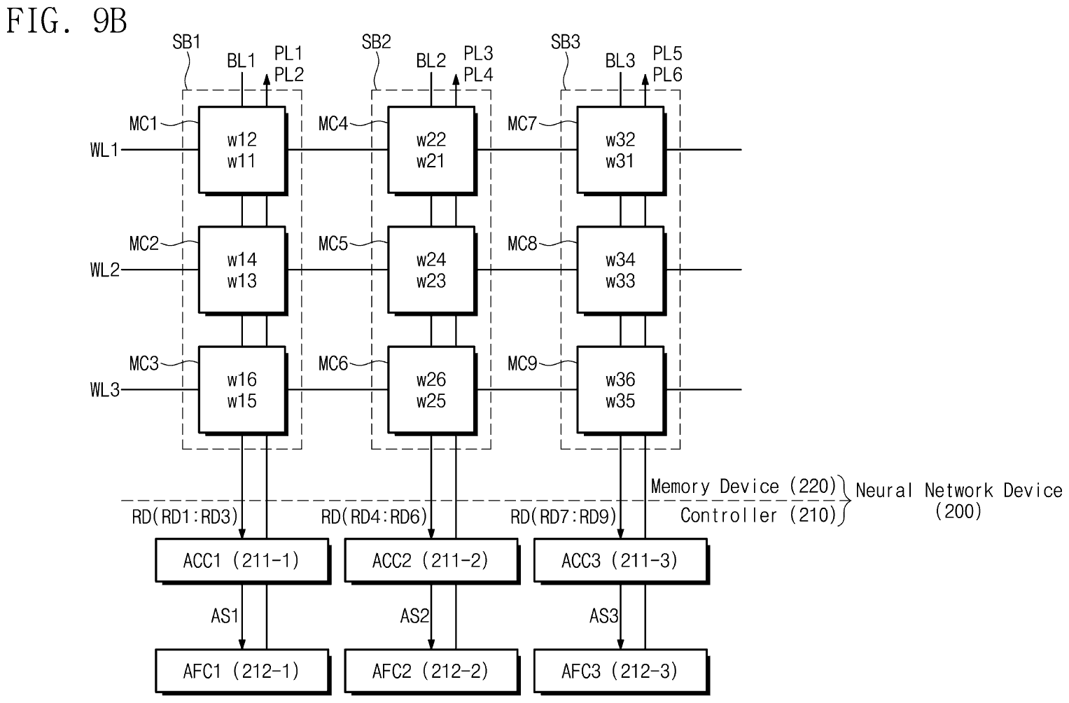

In some embodiments, the controller 110 may receive read data corresponding to the results of multiplication calculations of input data or activation signals and weights from the memory device 120. A more detailed description of how the controller 110 receives read data will be described later with reference to FIGS. 9A and 9B.

The controller 110 may include a plurality of accumulators 111-1 to 111-k and a plurality of activation function circuits 112-1 to 112-k. The controller 110 may include additional circuits (e.g., transistors, logic gates, and other integrated circuit components) and/or stored computer program code configured to perform the various functions described herein. The plurality of accumulators 111-1 to 111-k may generate accumulation signals (for example, corresponding to the accumulation values of FIG. 2). For example, the plurality of accumulators 111-1 to 111-k may receive read data from the memory device 120, and perform accumulation operations on the read data to generate accumulation signals, respectively. The plurality of accumulators 111-1 to 111-k may provide the accumulation signals to the plurality of activation function circuits 112-1 to 112-k, respectively. The accumulation signals generated by the plurality of accumulators 111-1 to 111-k may correspond to accumulation operations being performed on the first to sixth hidden nodes HN1 to HN6 in the neural network operation of FIG. 2.

The plurality of activation function circuits 112-1 to 112-k may generate activation signals (for example, corresponding to the activation values of FIG. 2). For example, the plurality of activation function circuits 112-1 to 112-k may generate activation signals by performing activation function calculations on accumulation signals received from the plurality of accumulators 111-1 to 111-k, respectively. Each activation function may include, for example, a sigmoid function, a tangent hyperbolic (tanh) function, a rectified linear unit (ReLU) function, a leaky ReLU function, an exponential linear unit (ELU) function, a softmax function, a Swish function, or a Gaussian error linear unit (GELU) function.

A more detailed description of the plurality of accumulators 111-1 to 111-k and the plurality of activation function circuits 112-1 to 112-k will be described later with reference to FIGS. 9A and 9B.

Under the control of an external device (e.g., the controller 110), the memory device 120 may store data (e.g., weights), or may output the results of multiplication calculations of stored data (e.g., weights) and input data (e.g., input data or activation signals) as read data.

The memory device 120 may include a memory cell array 121, a row decoding circuit 122, a sense amplifier/write driver 123, an input/output (I/O) circuit 124, and a control logic circuit 125.

The memory cell array 121 may include a plurality of memory cells MC. The plurality of memory cells MC may be arranged in rows and columns. The plurality of memory cells MC may be connected to word lines WL, the plate lines PL, and bit lines BL. For example, memory cells located in the same row among the plurality of memory cells MC may be connected to the same word line. The memory cells MC located in the same column among the plurality of memory cells MC may be connected to the same plate line PL or the same bit line BL. However, the arrangement of the memory cells MC is only an example, and the scope of the present disclosure is not limited thereto.

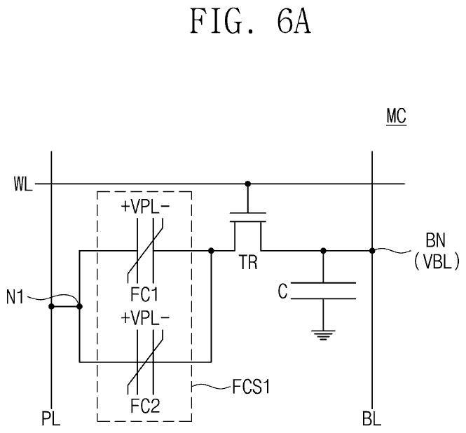

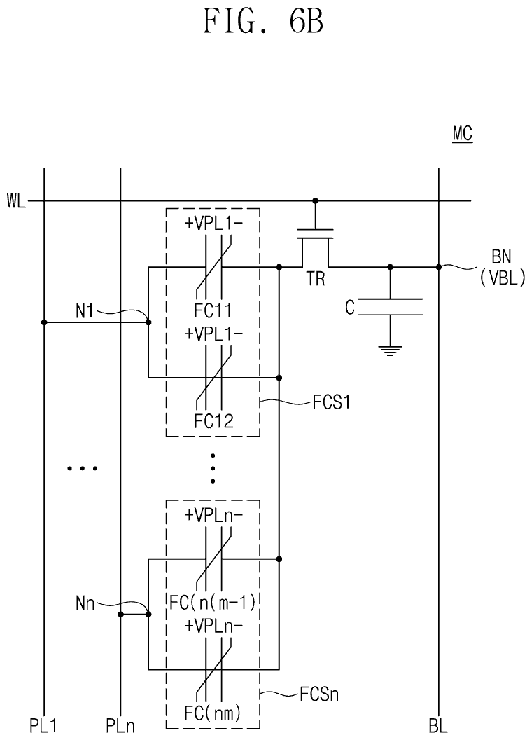

Each of the plurality of memory cells MC may store weights (corresponding to the weights in FIG. 2) for neural network operation. For example, each of the plurality of memory cells MC may store the weights of layers within a neural network. In some embodiments, each of the plurality of memory cells MC may store the weight of one layer, or the weights of at least two layers. A more detailed description of the plurality of memory cells MC, each of which stores one or more weights, will be described later with reference to FIGS. 6A and 6B.

In some embodiments, each of the plurality of memory cells MC included in the memory cell array 121 may be a ferroelectric memory cell. For example, the ferroelectric memory cell may include a ferroelectric capacitor. The ferroelectric capacitor has a characteristic in which a polarization state or a polarization value may change depending on a voltage at both ends, and the polarization state or the polarization value is maintained even when the voltage at both ends are blocked. For example, the ferroelectric memory cell may have the characteristics of a nonvolatile memory that may maintain information or data for a specific time depending on the polarization state or the polarization value of the ferroelectric capacitor.

In some embodiments, each of the plurality of memory cells MC included in the memory cell array 121 may be one of a static random access memory (SRAM) cell, a dynamic random access memory (DRAM) cell, a thyristor random access memory (TRAM) cell, a NAND flash memory cell, a NOR flash memory cell, a resistive random access memory (RRAM) cell, a phase change random access memory (PRAM) cell, and a magnetic random access memory (MRAM) cell.

The row decoding circuit 122 may be connected to the memory cell array 121 through the word lines WL. The row decoding circuit 122 may control the voltage of the word lines WL under the control of the control logic circuit 125. In some embodiments, the row decoding circuit 122 may decode a row address received from an external device (e.g., the controller 110) and may control voltages of the word lines WL based on the decoding result.

The sense amplifier/write driver 123 may be connected to the memory cell array 121 through the plate lines PL and the bit lines BL. The sense amplifier/write driver 123 receives data (e.g., input data or activation signals) from the I/O circuit 124 through the data lines DL, and may control the voltages of the plate lines PL and the bit lines BL based on the received data (e.g., input data or activation signals). The sense amplifier/write driver 123 may detect voltage changes of the bit lines BL and may read out the results of multiplication calculations of weights stored in the memory cell array 121 and received data (input data or activation signals) based on the detected voltage changes.

The I/O circuit 124 may exchange data with an external device (e.g., the controller 110). The I/O circuit 124 may deliver data (e.g., input data or activation signals) to the sense amplifier/write driver 123 through the data lines DL, or may receive read data (e.g., corresponding to the result of multiplication calculations of weights and input data) from the sense amplifier/write driver 123 via the data lines DL.

The control logic circuit 125 may control overall operations of the memory device 120. For example, the control logic circuit 125 may control the row decoding circuit 122, the sense amplifier/write driver 123, and the I/O circuit 124 such that the memory device 120 performs a write operation, a read operation, or a multiplication calculation (e.g., performed by a multiplying circuit in the controller 110).

The memory device 120 described with reference to FIG. 3 is only an example to easily explain an embodiment of the present disclosure, and the scope of the present disclosure is not limited thereto. Depending on how the memory device 120 is implemented, the memory device 120 may further include a command buffer, an address buffer, or the like.

In some embodiments, the memory device 120 may have architecture similar to the architecture of a DRAM device and may communicate with an external device based on the interface (e.g., DDR, LPDDR, or the like) of the DRAM device. Alternatively, the memory device 120 may communicate with an external device (e.g., a controller, a CPU, an AP, or the like) through various other interfaces such as an Advanced Technology Attachment (ATA) interface, a Serial ATA (SATA) interface, an external SATA (e-SATA) interface, a Small Computer Small Interface (SCSI) interface, a Serial Attached SCSI (SAS) interface, a Peripheral Component Interconnection (PCI) interface, a PCI express (PCIe) interface, an NVM express (NVMe) interface, an IEEE 1394 interface, an Universal Serial Bus (USB) interface, a Secure Digital (SD) card interface, a Multi-Media Card (MMC) interface, an embedded Multi-Media Card (eMMC) interface, an Universal Flash Storage (UFS) interface, an embedded Universal Flash Storage (eUFS) interface, or a Compact Flash (CF) card interface.

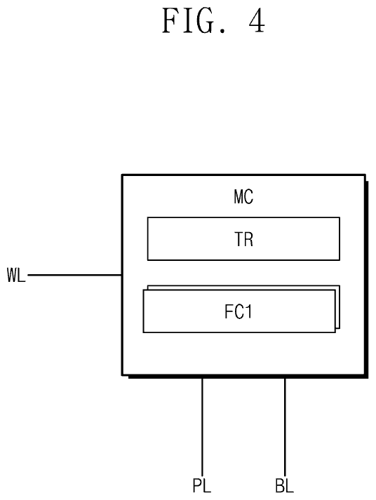

FIG. 4 is a block diagram of a memory cell, according to an embodiment of the present disclosure. Referring to FIG. 4, the memory cell MC may include the transistor TR and a plurality of ferroelectric capacitors including a first ferroelectric capacitor FC1. The ferroelectric capacitor is described to help understanding of the present disclosure and is not intended to limit the scope of the present disclosure. The memory cell MC may include one of a ferroelectric capacitor, a capacitor, and a resistor transistor.

The first ferroelectric capacitor FC1 may include a dielectric film composed of a ferroelectric material, an antiferroelectric material, a paraelectric material, or a combination thereof. In some embodiments, the ferroelectric material may include a pervoskite material such as BaTiOx and a fluorite material of the hafnium (Hf) series, HfxZr1-xOy. The antiferroelectric material may include materials such as ZrO2, HfxZr1-xOy, PbZrO3, and NaNbO3. The ferroelectric material or the antiferroelectric material may be a fluorite material of the hafnium (Hf) series, or may include a rare earth element of the La series in HfxZr1-xOy material. The ferroelectric material or the antiferroelectric material may include hafnium oxide. The paraelectric material may include a high-dielectric material such as BeO2, MaO2, CaO2, SrO2, Al2O3, Y2O3, Sc2O3, La2O3, HfO2, ZrO2, TiO2, Ta2O5, Nb2O5, V2O5, SrTiO3, or BaSrTiO3.

In some embodiments, the first ferroelectric capacitor FC1 may include a dielectric film made of the ferroelectric material. In this case, the polarization state or polarization value of the first ferroelectric capacitor FC1 may vary depending on a voltage at both ends, and even when the voltage at both ends are blocked, the polarization state or polarization value may be maintained for a specific time. Depending on data or information to be stored in the memory cell MC, the polarization state or polarization value of the ferroelectric capacitor FC may be set or adjusted differently. In this case, pieces of data (e.g., weights) or pieces of information may be stored in the memory cell MC.

Hereinafter, for convenience of description, it is assumed that the memory cell MC is a memory cell including a plurality of ferroelectric capacitors as described with reference to FIGS. 6A and 6B. The polarization states of the plurality of ferroelectric capacitors may be expressed as negative or positive numbers. In this case, it may be understood that the negative or positive numbers of the polarization states indicate the directionality of the polarization states of the plurality of ferroelectric capacitors.

Hereinafter, for convenience of description, it is described that the polarization states of the plurality of ferroelectric capacitors respectively have symmetrical characteristics based on the voltage at both ends, respectively. In this case, when the voltage at both ends is 0 V, the polarization states of the plurality of ferroelectric capacitors may be stabilized. However, the scope of the present disclosure is not limited thereto. The polarization states of the plurality of ferroelectric capacitors may have asymmetrical characteristics based on the voltage at both ends, respectively. In this case, at a voltage other than 0 V, the polarization states of the plurality of ferroelectric capacitors may be stabilized.

The transistor TR may be turned on or off. For example, the transistor TR may be turned on or off by the voltage level of a signal applied through the word line WL. When the transistor TR is turned on, the memory cell MC may store data (e.g., a weight) or may provide data (e.g., read data) to the sense amplifier/write driver 123 of FIG. 3 through the bit line BL.

The memory cell MC may include at least two ferroelectric capacitors including the first ferroelectric capacitor FC1. The memory cell MC may store weights by using at least two ferroelectric capacitors. In some embodiments, the memory cell MC may receive weight data including weights through the plate line PL, and may store the weights by using at least two ferroelectric capacitors based on the received weight data.

The memory cell MC may receive the plate voltage (corresponding to input data) through the plate line PL connected to at least two ferroelectric capacitors. An operation of multiplying input data (or activation signals) and a weight may be performed based on the voltage level of the plate voltage and the weight stored in the memory cell MC. There may be a voltage change corresponding to the result of multiplying input data (or activation signals) and the weight in the bit line BL connected to the memory cell MC. As described above in FIG. 3, the sense amplifier/write driver 123 of FIG. 3, which is connected through the memory cell MC and the bit line BL, may detect the voltage change of the bit line BL, and may read out the result of the multiplication calculation in the memory cell MC based on the detected voltage change.

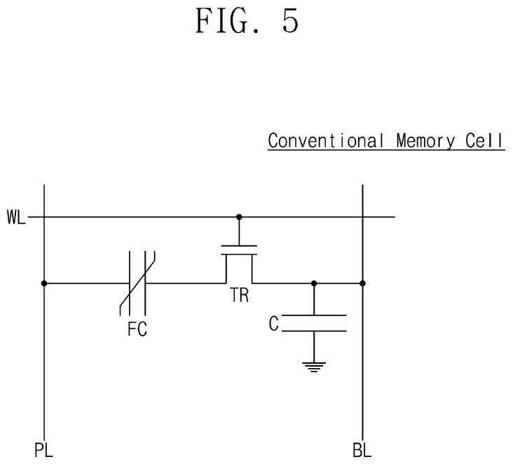

FIG. 5 is a circuit diagram for describing a conventional memory cell. Referring to FIG. 5, the conventional memory cell may include the transistor TR, one ferroelectric capacitor FC, and a capacitor C. For example, the conventional memory cell may have 1-Transistor 1-Capacitor (1T1C) architecture.

The conventional memory cell may store data (e.g., a weight) based on a polarization state of the ferroelectric capacitor FC. Because the conventional memory cell includes the one ferroelectric capacitor FC, the conventional memory cell may store a weight having two levels (e.g., the first level corresponding to ‘0’ and the second level corresponding to ‘1’). That is, the conventional memory cell may store only a weight for binarized neural network operations. Accordingly, the conventional memory cell may be unsuitable for being used as a component of a neural network device performing various neural network operations.

Because the conventional memory cell stores one binary (e.g., having two levels) weight in one ferroelectric capacitor FC, the conventional memory cell may have lower storage density, lower cost efficiency, and lower power efficiency than the memory cell according to an embodiment of the present disclosure which may store one or more weights having a plurality of levels.

FIG. 6A is a circuit diagram for describing a memory cell, according to some embodiments of the present disclosure. Referring to FIG. 6A, the memory cell MC may include the transistor TR, the first ferroelectric capacitor FC1, a second ferroelectric capacitor FC2, and the capacitor C. The first ferroelectric capacitor FC1 and the second ferroelectric capacitor FC2 of the memory cell MC are described to help understanding of the present disclosure and are not intended to limit the scope of the present disclosure. The memory cell MC may include a different number of ferroelectric capacitors, as will be described later with reference to FIG. 6B.

The memory cell MC may be connected to the word line WL, the bit line BL, and the plate line PL. The transistor TR of the memory cell MC may be controlled by the word line WL. For example, the transistor TR may be connected to the word line WL through its gate terminal, and may be turned on or off based on the voltage level (e.g., a power supply voltage or a ground voltage) of a voltage applied from the word line WL.

The first terminal of the transistor TR may be connected to the first ferroelectric capacitor FC1 and the second ferroelectric capacitor FC2, and the second terminal thereof may be connected to the bit line BL at a bit line node BN.

The first ferroelectric capacitor FC1 and the second ferroelectric capacitor FC2 may be connected between the plate line PL and the transistor TR. For example, the first ferroelectric capacitor FC1 and the second ferroelectric capacitor FC2 may be connected in parallel between the plate line PL and the transistor TR. Accordingly, the first ferroelectric capacitor FC1 and the second ferroelectric capacitor FC2 may receive the same plate voltage VPL through one plate line PL.

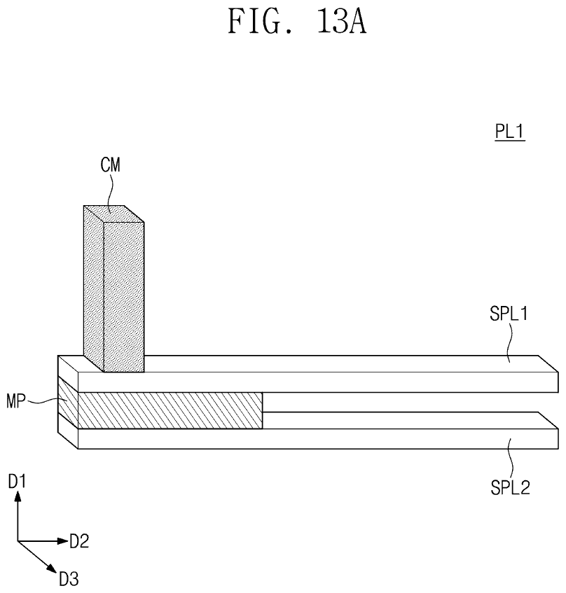

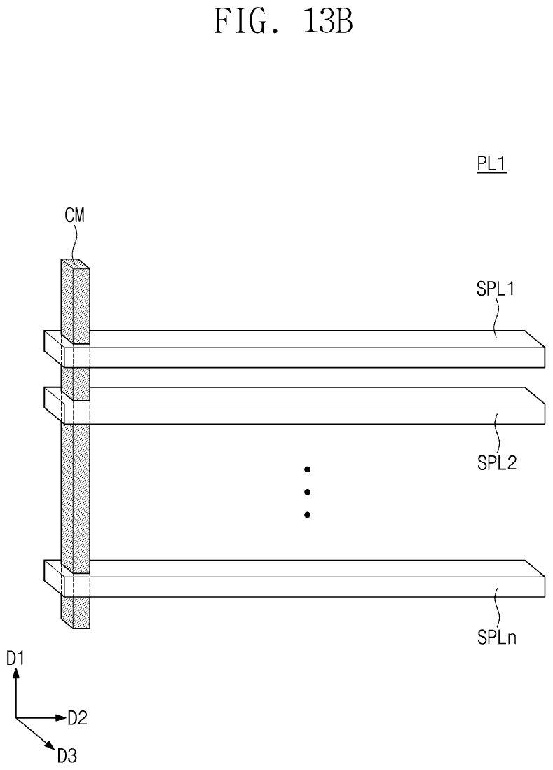

In some embodiments, the first ferroelectric capacitor FC1 and the second ferroelectric capacitor FC2 may be connected to one of the plate lines PL at a first node N1. For example, the first ferroelectric capacitor FC1 and the second ferroelectric capacitor FC2 may be connected to the plate line PL formed by merging a first sub-plate line connected to the first ferroelectric capacitor FC1 and a second sub-plate line connected to the second ferroelectric capacitor FC2 at the first node N1. The forming of the plate line by merging the first sub-plate line and the second sub-plate line will be described later with reference to FIGS. 13A and 13B.

In some embodiments, the plate line PL may be formed by merging a first plate line, to which the first ferroelectric capacitor FC1 is connected, and a second plate line, to which the second ferroelectric capacitor FC2 is connected, at the first node N1.

A first ferroelectric capacitor set FCS1 may include a plurality of ferroelectric capacitors. For convenience of description, FIG. 6A illustrates the first ferroelectric capacitor set FCS1 including the first and second ferroelectric capacitors FC1 and FC2. However, the present disclosure is not limited thereto. For example, the first ferroelectric capacitor set FCS1 may include more than two ferroelectric capacitors.

In some embodiments, the first ferroelectric capacitor FC1 and the second ferroelectric capacitor FC2 may be a first ferroelectric capacitor set FCS1. The first ferroelectric capacitor set FCS1 may include the first ferroelectric capacitor FC1 and the second ferroelectric capacitor FC2, each of which is connected to the one plate lines PL (which may be a line including sub-plate lines or plate lines that are merged).

In some embodiments, the first ferroelectric capacitor set FCS1 may store one weight. For example, the first ferroelectric capacitor FC1 and the second ferroelectric capacitor FC2 of the first ferroelectric capacitor set FCS1 may have the same polarization states indicating a level (e.g., a first level indicating logic low or a second level indicating logic high) of one weight, respectively.

In some embodiments, when the transistor TR is turned on, a bit line voltage VBL of the bit line node BN may be determined based on the polarization states (or stored weights) of the first ferroelectric capacitor FC1 and the second ferroelectric capacitor FC2 and the plate voltage VPL. For example, when the polarization states of the first ferroelectric capacitor FC1 and the second ferroelectric capacitor FC2 indicate the first level, which is logic low (e.g., when the value of the stored weight is 0), the bit line voltage VBL may change by a first voltage change to maintain the polarization state based on the plate voltage VPL being a ground voltage (e.g., 0 V).

In some embodiments, when the polarization states of the first ferroelectric capacitor FC1 and the second ferroelectric capacitor FC2 indicate the second level, which is logic high (e.g., when the value of the stored weight is 1), the bit line voltage VBL may change by a second voltage change to change the polarization state based on the plate voltage VPL being the ground voltage (e.g., 0 V).

In some embodiments, the neural network device 100 of FIG. 3 may output the result of an operation of multiplying the weight stored in the memory cell MC and the input data corresponding to the plate voltage as read data based on a voltage change (e.g., a first voltage change or a second voltage change) of the bit line voltage VBL. In detail, the sense amplifier/write driver 123 of FIG. 3 may detect the voltage change (e.g., the first voltage change or the second voltage change) of the bit line BL, and may read out the result of the operation of multiplying the weight stored in the memory cell MC and the received data (input data or activation signals) as read data based on the detected voltage change (e.g., the first voltage change or the second voltage change).

The memory cell MC may have the architecture of 1TnC (1 Transistor ‘n’ Capacitors). For example, the memory cell MC may include one transistor and at least two ferroelectric capacitors. Unlike the conventional memory cell of FIG. 5 where one ferroelectric capacitor stores one weight, the memory cell MC may be more stable storage for storing a weight by storing one weight by using a plurality of (e.g., at least two) ferroelectric capacitors (i.e., one ferroelectric capacitor set).

FIG. 6B is a circuit diagram for describing a memory cell, according to some embodiments of the present disclosure. Referring to FIG. 6B, the memory cell MC may include the transistor TR, a plurality of ferroelectric capacitor sets FCS1 to FCSn, and the capacitor C. Because the memory cell MC is somewhat similar to the memory cell MC of FIG. 6A, a redundant description of the memory cell MC will be omitted. ‘n’ is an integer greater than or equal to 3.

The memory cell MC may be connected to one word line, one bit line, and a plurality of plate lines PL1 to PLn. The memory cell MC may include the plurality of ferroelectric capacitor sets FCS1 to FCSn, which are respectively connected to the plurality of plate lines PL1 to PLn.

The plurality of ferroelectric capacitor sets FCS1 to FCSn may include the plurality of ferroelectric capacitors FC11 to FC(nm). The ferroelectric capacitors within a ferroelectric capacitor set are each connected to one plate line and may have the same polarization states as each other. Each of the plurality of ferroelectric capacitor sets FCS1 to FCSn may include ‘m’ ferroelectric capacitors. ‘m’ is an integer greater than or equal to 2.

For example, the first ferroelectric capacitor set FCS1 may include a plurality of ferroelectric capacitors including the first and second ferroelectric capacitors FC11 and FC12. The plurality of ferroelectric capacitors may be connected to the first plate line PL1 at the first node N1. In some embodiments, the first plate line PL1 may be formed by merging a plurality of sub-plate lines, which are respectively connected to the plurality of ferroelectric capacitors, at the first node N1.

In some embodiments, the plurality of ferroelectric capacitor sets FCS1 to FCSn may store a single weight having one of a plurality of levels. The weight stored in the plurality of ferroelectric capacitor sets FCS1 to FCSn may have one of (n+1) levels.

For example, when all of the plurality of ferroelectric capacitor sets have polarization states indicating a ground voltage (or logic low), the stored weight may be a first level indicating ‘0’ (or logic low). Moreover, when all of the plurality of ferroelectric capacitor sets have polarization states indicating a power supply voltage (or logic high), the stored weight may be a (n+1)-th level indicating ‘n’. Similarly, when ‘p’ ferroelectric capacitor sets among the plurality of ferroelectric capacitor sets have polarization states indicating the power supply voltage (or logic high), the stored weight may be a (p+1)-th level indicating ‘p’. ‘p’ is an integer greater than ‘0’ and less than ‘n’.

In some embodiments, the plurality of ferroelectric capacitor sets FCS1 to FCSn may store at least two weights. For example, some of the plurality of ferroelectric capacitor sets FCS1 to FCSn may store the first weight, and the others may store the second weight. The first weight and the second weight may be included in different layers from each other or the same layers as each other within the neural network of FIG. 2. Each of the first weight and the second weight may have two or more levels. The weight data stored by a ferroelectric capacitor set of a memory cell may be a piece of data, for example, used with other data, to result in a weight having one of the levels.

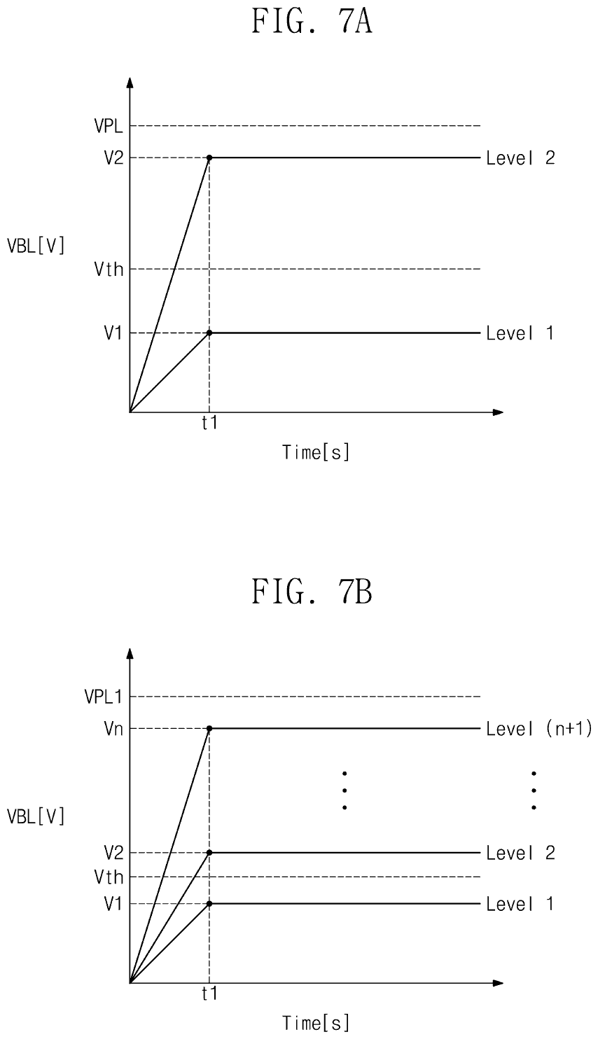

FIG. 7A is a graph for describing a level of a weight, according to some embodiments of the present disclosure. Referring to FIG. 7A, a horizontal axis indicates time, and a vertical axis indicates a voltage change at the bit line BL to which the memory cell MC of FIG. 6A is connected.

When the first and second ferroelectric capacitors FC1 and FC2 of the memory cell MC of FIG. 6A receive the plate voltage VPL through the plate line PL, the plate voltage VPL may be applied to a respective end of each of the first and second ferroelectric capacitors FC1 and FC2.

At a first time point t1, the bit line voltage VBL corresponding to the voltage change may be determined based on a value (e.g., 0 or 1) of the weight stored in the first and second ferroelectric capacitors FC1 and FC2. For example, when the weight stored by the first and second ferroelectric capacitors FC1 and FC2 is at a first level, the bit line voltage VBL may be a first voltage V1 lower than a threshold value Vth. When the weight is at a second level, the bit line voltage VBL may be a second voltage V2 higher than the threshold value Vth and lower than the plate voltage VPL.

FIG. 7B is a graph for describing a level of a weight, according to some embodiments of the present disclosure. Referring to FIG. 7B, a horizontal axis indicates time, and a vertical axis indicates a voltage change at the bit line BL to which the memory cell MC of FIG. 6B is connected.

When the plurality of ferroelectric capacitor sets FCS1 to FCSn of the memory cell MC of FIG. 6B respectively receive plate voltages VPL1 to VPLn through the plurality of plate lines PL1 to PLn, the plate voltages VPL1 to VPLn may be applied to both terminals of the ferroelectric capacitors of the plurality of ferroelectric capacitor sets FCS1 to FCSn.

In some embodiments, when the memory cell MC stores one weight, the weight may have one of (n+1) levels. At the first time point t1, the bit line voltage VBL corresponding to a voltage change may be generated based on a value (e.g., one of 0 to ‘n’) of the weight stored in the memory cell MC.

For example, when the weight stored by the first and second ferroelectric capacitors FC1 and FC2 is at a first level, the bit line voltage VBL may be the first voltage V1 lower than the threshold value Vth. When the weight is at the second level, the bit line voltage VBL may be the second voltage V2 higher than the threshold value Vth. Finally, when the weight is at a (n+1)-th level, the bit line voltage VBL may be an n-th voltage Vn, which is higher than the bit line voltage VBL at a point in time when the weight is at an n-th level and which is lower than the first plate voltage VPL1.

Therefore, when the memory cell MC storing one weight includes the plurality of ferroelectric capacitor sets FCS1 to FCSn, the weight may be an amount selected from a maximum of (n+1) levels.

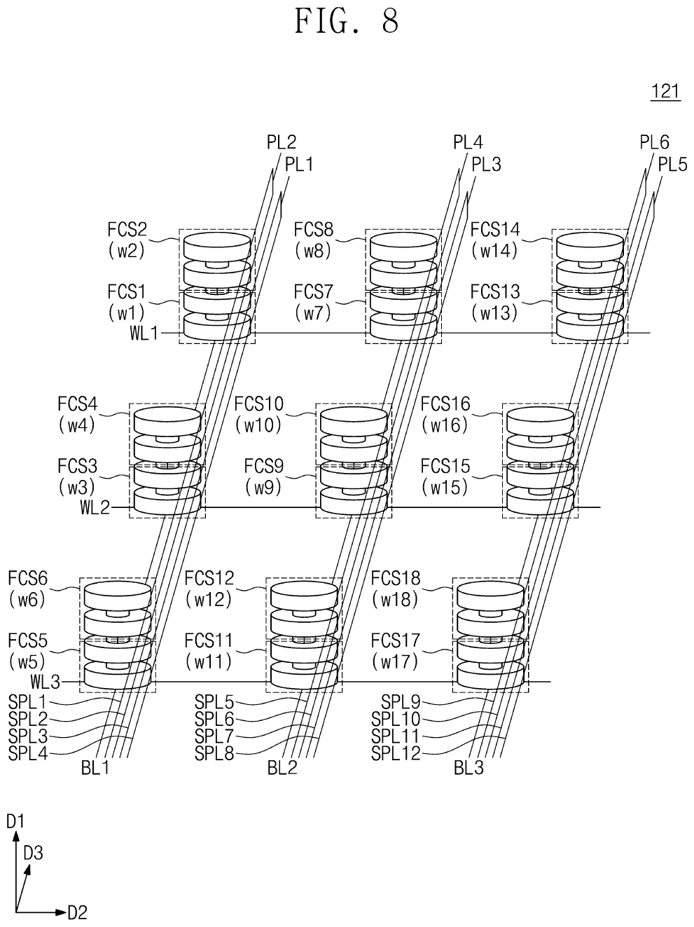

FIG. 8 is a diagram for describing a memory cell array, according to some embodiments of the present disclosure. Referring to FIG. 8, the memory cell array 121 may include a plurality of ferroelectric capacitor sets FCS1 to FCS18 arranged in three rows and three columns. The memory cell array 121 is described to help understanding of the present disclosure and is not intended to limit the scope of the present disclosure. The memory cell array 121 may include the different number and arrangement of memory cells, ferroelectric capacitor sets, ferroelectric capacitors, and weights from those described.

The plurality of ferroelectric capacitor sets FCS1 to FCS18 may be positioned in a plurality of stages sequentially stacked in a first direction D1. For example, some of the plurality of ferroelectric capacitor sets FCS1 to FCS18 may be located in the first stage, and the others may be located in the second stage, which is stacked in the first direction D1 with respect to the first stage.

In some embodiments, among the first to sixth ferroelectric capacitor sets FCS1 to FCS6 connected to the first bit line BL1, the first, third, and fifth ferroelectric capacitor sets FCS1, FCS3, and FCS5 may be located in the first stage, and the second, fourth, and sixth ferroelectric capacitor sets FCS2, FCS4, and FCS6 may be located in the second stage, which is stacked in the first direction D1 with respect to the first stage. Therefore, each of memory cells connected to a bit line may include ferroelectric capacitor sets located in a plurality of stages (e.g., the first and second stages).

Among ferroelectric capacitors connected to the same bit line, some located on the same stage may be connected to the same plate line. For example, among the first to sixth ferroelectric capacitor sets FCS1 to FCS6 connected to the first bit line BL1, the first, third, and fifth ferroelectric capacitor sets FCS1, FCS3, and FCS5 located in the first stage may be connected to the first plate line PL1, and the second, fourth, and sixth ferroelectric capacitor sets FCS2, FCS4, and FCS6 located in the second stage may be connected to the second plate line PL2.

In some embodiments, one plate line may be formed by merging a plurality of sub-plate lines. For example, the first plate line PL1 may be formed by merging the first and second sub-plate lines. The first and second sub-plate lines PL1 and PL2 may be respectively connected to the ferroelectric capacitors in the first, third, and fifth ferroelectric capacitor sets FCS1, FCS3, and FCS5.

The plurality of ferroelectric capacitor sets FCS1 to FCS18 may store a plurality of weights w1 to w18, respectively. The plurality of weights w1 to w18 may be weights of different layers in the neural network or weights of a single layer. For example, some of the plurality of weights w1 to w18 may be weights of the first layer, and the others may be weights of the second layer, or all of the plurality of weights w1 to w18 may be weights of the first layer (or the second layer).

In some embodiments, among the ferroelectric capacitors connected to the same bit line, some located in the same stage may store weights of the same plate line. For example, among the plurality of ferroelectric capacitor sets FCS1 to FCS18, the first, third, fifth, seventh, ninth, eleventh, thirteenth, fifteenth, and seventeenth ferroelectric capacitor sets FCS1, FCS3, FCS5, FCS7, FCS9, FCS11, FCS13, FCS15, and FCS17 located in the first stage may store first, third, fifth, seventh, ninth, eleventh, thirteenth, fifteenth, and seventeenth weights w1, w3, w5, w7, w9, w11, w13, w15, and w17 of the first layer of the neural network, respectively. Therefore, the memory cell array 121 may store weights associated with one layer in ferroelectric capacitor sets located at one stage.

In some embodiments, among the plurality of ferroelectric capacitor sets FCS1 to FCS18, some located in the same column (e.g., connected to the same bit line) may store weights for the same layer. For example, among the plurality of ferroelectric capacitor sets FCS1 to FCS18, the first to sixth ferroelectric capacitor sets FCS1 to FCS6 connected to the first bit line BL1 may respectively store the first to sixth weights w1 to w6, which are the weights associated with the first layer of the neural network. Similarly, the seventh to twelfth ferroelectric capacitor sets FCS7 to FCS12 connected to the second bit line BL2 may respectively store the seventh to twelfth weights, which are the weights associated with the second layer of the neural network. Accordingly, the memory cell array 121 may store the weights associated with one layer in one unit (e.g., one sub-block) of ferroelectric capacitor sets.

FIG. 9A is a block diagram of a neural network device, according to some embodiments of the present disclosure. Referring to FIG. 9A, a neural network device 200 may include a controller 210 and a memory device 220. The neural network device 200 is somewhat similar to the neural network device 100 of FIG. 3, and thus redundant description will be omitted.

The controller 210 may communicate with the memory device 220. For example, the controller 210 may provide an address and data (e.g., weights, input data, or activation signals) to the memory device 220. In some embodiments, the controller 210 may provide input data to the memory device 220, and the input data (in the form of a voltage level) may be provided to a plurality of memory cells MC1 to MC9 of the memory device 220 through a plurality of plate lines PL1 to PL6.

The controller 210 may include first to third accumulators 211-1 to 211-3 and first to third activation function circuits 212-1 to 212-3. The controller 210 is described to help understanding of the present disclosure and is not intended to limit the scope of the present disclosure. The controller 210 may include the different number of accumulators and activation function circuits from those described.

The first to third accumulators 211-1 to 211-3 may receive read data RD from the memory device 220. For example, the first to third accumulators 211-1 to 211-3 may receive the read data RD corresponding to the result of multiplying weights and input data or activation signals from the memory device 220.

In some embodiments, the first to third accumulators 211-1 to 211-3 may receive the read data RD corresponding to the result of multiplying weights w11 to w19 and w21 to w29, which are stored in the plurality of memory cells MC1 to MC9, and input data or activation signals from the memory device 220.

For example, when the controller 210 provides input data (i.e., a plate voltage) to the first to third memory cells MC1 to MC3 (or ferroelectric capacitor sets connected to the first plate line PL1) through the first plate line PL1, the first accumulator 211-1 may receive the first to third read data RD1 to RD3 corresponding to the result of multiplying the weights w11 to w13 (e.g., of the first layer) stored in the first to third memory cells MC1 to MC3 (or ferroelectric capacitor sets connected to the first plate line PL1) and the input data output from the memory device 220 through the first bit line BL1.

The first to third accumulators 211-1 to 211-3 may generate first to third accumulation signals AS1 to AS3 by performing accumulation operations on the read data RD. For example, the first accumulator 211-1 may generate the first accumulation signal AS1 by performing an accumulation operation on the first to third read data RD1 to RD3 (e.g., each read data being a result of multiplying an input data by a respective weight). Similarly, the second and third accumulators 211-2 and 211-3 may generate the second and third accumulation signals AS2 and AS3 by performing an accumulation operation on fourth to sixth read data RD4 to RD6 and performing an accumulation operation of seventh to ninth read data RD7 to RD9.

The first to third accumulators 211-1 to 211-3 may provide the first to third accumulation signals AS1 to AS3 to the first to third activation function circuits 212-1 to 212-3, respectively.

The first to third activation function circuits 212-1 to 212-3 may generate first to third activation signals, respectively. For example, the first to third activation function circuits 212-1 to 212-3 may generate first to third activation signals by performing activation function calculations on the first to third accumulation signals AS1 to AS3 received from the first to third accumulators 211-1 to 211-3. The activation function may be a function that outputs a value, such as one of two voltages, depending on a particular calculation performed in inputs, such as the accumulation signals, and may include, for example, a sigmoid function, a tangent hyperbolic (tanh) function, a rectified linear unit (ReLU) function, a leaky ReLU function, an exponential linear unit (ELU) function, a softmax function, a Swish function, and a Gaussian error linear unit (GELU) function.

The controller 210 may provide the first to third activation signals to the memory device 220. For example, the controller 210 may provide the generated first to third activation signals to the memory device 220 to perform calculations on the next layer (e.g., a second layer) in a neural network. In some embodiments, the controller 210 may provide first to third activation signals (e.g., input data of the second layer) to the plurality of memory cells MC1 to MC9 through the first to sixth plate lines PL1 to PL6. Afterward, the first to third accumulators 211-1 to 211-3 may receive the read data RD corresponding to the results of multiplying the first to third activation signals and the weights w21 to w29 (e.g., of the second layer) from the memory device 220.

The first to third accumulators 211-1 to 211-3 may respectively generate accumulation signals by performing accumulation operations on read data, and may respectively provide the generated accumulation signals to the first to third activation function circuits 212-1 to 212-3.

The memory device 220 may include the plurality of memory cells MC1 to MC9. For example, the memory device 220 may include the plurality of memory cells MC1 to MC9 arranged in three rows and three columns. The plurality of memory cells MC1 to MC9 may include ferroelectric capacitor sets, respectively. The memory device 220 is described to help understanding of the present disclosure and is not intended to limit the scope of the present disclosure. The memory device 220 may include a different number and arrangement of memory cells from those described.

For convenience of description, the description of other components (e.g., the row decoding circuit 122, the sense amplifier/write driver 123, the I/O circuit 124, and the control logic circuit 125 of FIG. 3) within the memory device 220 excluding the plurality of memory cells MC1 to MC9 is omitted below.

The plurality of memory cells MC1 to MC9 may store a plurality of weights, respectively. For example, the plurality of memory cells MC1 to MC9 may store the weights w11 to w19 of the first layer and the weights w21 to w29 of the second layer in the neural network, respectively.

In some embodiments, for example, each of the plurality of memory cells MC1 to MC9 may include two ferroelectric capacitor sets. The two ferroelectric capacitor sets may be connected to two plate lines, respectively. The two ferroelectric capacitor sets may store weights of the first layer and weights of the second layer, respectively.

For example, the first memory cell MC1 may store the first weight w11 of the first layer and the first weight w21 of the second layer. In more detail, the first memory cell MC1 may store the first weight w11 of the first layer in a ferroelectric capacitor set connected to the first plate line PL1, and the first weight w21 of the second layer in a ferroelectric capacitor set connected to the second plate line PL2.

Similarly, the second and third memory cells MC2 and MC3 may respectively store the second and third weights w12 and w13 of the first layer in the ferroelectric capacitor sets connected to the first plate line PL1, and may respectively store the second and third weights w22 and w23 of the second layer in the ferroelectric capacitor sets connected to the second plate line PL2. Therefore, each of the plurality of memory cells MC1 to MC9 may store weights of different layers in ferroelectric capacitor sets connected to different plate lines.

The plurality of memory cells MC1 to MC9 may provide the read data RD to the controller 210. In more detail, the memory device 220 may generate the read data RD based on voltage changes of the first to third bit lines BL1 to BL3, to which the plurality of memory cells MC1 to MC9 are connected, and may provide the generated read data RD to the controller 210.

In some embodiments, the plurality of memory cells MC1 to MC9 may receive input data or activation signals (e.g., first to third activation signals) from the controller 210 through the first to sixth plate lines PL1 to PL6. For example, the plurality of memory cells MC1 to MC9 may simultaneously receive input data through the first to third plate lines PL1 to PL3, and then may simultaneously receive activation signals (e.g., first to third activation signals) through the fourth to sixth plate lines PL4 to PL6.

In some embodiments, the plurality of memory cells MC1 to MC9 may read out the stored weights w11 to w19 and w21 to w29 based on the received input data or activation signals (e.g., first to third activation signals), and may provide the read data RD corresponding to the results of multiplication calculations to the first to third accumulators 211-1 to 211-3.

For example, among the plurality of memory cells MC1 to MC9, the first, fourth, and seventh memory cells MC1, MC4, and MC7 connected to the first word line WL1 may simultaneously receive input data through the first, third, and fifth plate lines PL1, PL3, and PL5, and provide the first to third accumulators 211-1 to 211-3 with the first, fourth, and seventh read data RD1, RD4, and RD7 corresponding to the results of multiplying the input data and the stored weights w11, w14, and w17. Afterward, the second, fifth, and eighth memory cells MC2, MC5, and MC8, which are connected to the second word line WL2, from among the plurality of memory cells MC1 to MC9 may simultaneously receive input data through the first, third, and fifth plate lines PL1, PL3, and PL5, and may provide the first to third accumulators 211-1 to 211-3 with the second, fifth, and eighth read data RD2, RD5, and RD8 corresponding to the results of multiplying the input data and the stored weights w12, w15, and w18.

In some embodiments, the memory device 220 may simultaneously receive plate voltages (e.g., input data or activation signals) through the first to third plate lines PL1 to PL3 or the fourth to sixth plate lines PL4 to PL6 in the plurality of memory cells MC1 to MC9, thereby quickly and efficiently performing a portion of a neural network operation.

FIG. 9B is a block diagram of a neural network device, according to some embodiments of the present disclosure. Referring to FIG. 9B, the neural network device 200 may include the controller 210 and the memory device 220. The neural network device 200 is somewhat similar to the neural network device 200 of FIG. 9A, and thus redundant description will be omitted.

The memory device 220 may include first to third sub-blocks SB1 to SB3. The first to third sub-blocks SB1 to SB3 may include the memory cells MC1 to MC9 connected to the first to third bit lines BL1 to BL3. For example, the first sub-block SB1 may include the first to third memory cells MC1 to MC3 connected to the first bit line BL1. The first to third sub-blocks SB1 to SB3 is described to help understanding of the present disclosure and is not intended to limit the scope of the present disclosure. The first to third sub-blocks SB1 to SB3 may include the different number and arrangement of memory cells from those described. In one embodiment, the first to third sub-blocks SB1 to SB3 may include the memory cells MC1 to MC9 connected to the first to third word lines WL1 to WL3.

The first to third sub-blocks SB1 to SB3 may store the weights of different layers within a neural network. For example, the first sub-block SB1 may store the weights w11 to w16 of a first layer; the second sub-block SB2 may store the weights w21 to w26 of a second layer; and, the third sub-block SB3 may store weights w31 to w36 of a third layer.

In some embodiments, the first to third sub-blocks SB1 to SB3 may sequentially receive input data and activation signals from the controller 210 through corresponding plate lines.

For example, the first sub-block SB1 may receive input data through the first and second plate lines PL1 and PL2; the second sub-block SB2 may receive first activation signals (which are the results of performing an accumulation operation and an activation operation on the results of multiplication calculations of input data and weights) through the third and fourth plate lines PL3 and PL4; and the third sub-block SB3 may receive second activation signals (which are the results of performing an accumulation operation and an activation operation on the results of multiplication calculations of first activation signals and weights) through the fifth and sixth plate lines PL5 and PL6.

In some embodiments, after weights stored in the first to third sub-blocks SB1 to SB3 are read out and multiplication calculations on the stored weights and received input data or activation signals are performed, the controller 210 may re-write the weights in the first to third sub-blocks SB1 to SB3.

For example, after the weights w11 to w16 stored in the first sub-block SB1 are read out, and the results of the multiplication calculations of the input data and the weights w11 to w16 are provided to the controller 210 as the read data RD, the controller 210 may re-write the weights w11 to w16 in the first sub-block SB1. While or before the controller 210 re-writes the weights w11 to w16 into the first sub-block SB1, the controller 210 may provide activation signals (e.g., first activation signals) to the second sub-block SB2.

Therefore, the controller 210 may perform calculations on the first layer in the neural network, and then may re-write the weights of the first layer to the memory device 220 during or before performing calculations on the second layer. In this manner, the neural network device 200 may perform neural network operations efficiently and quickly by re-writing weights and performing neural network operations at the same time.

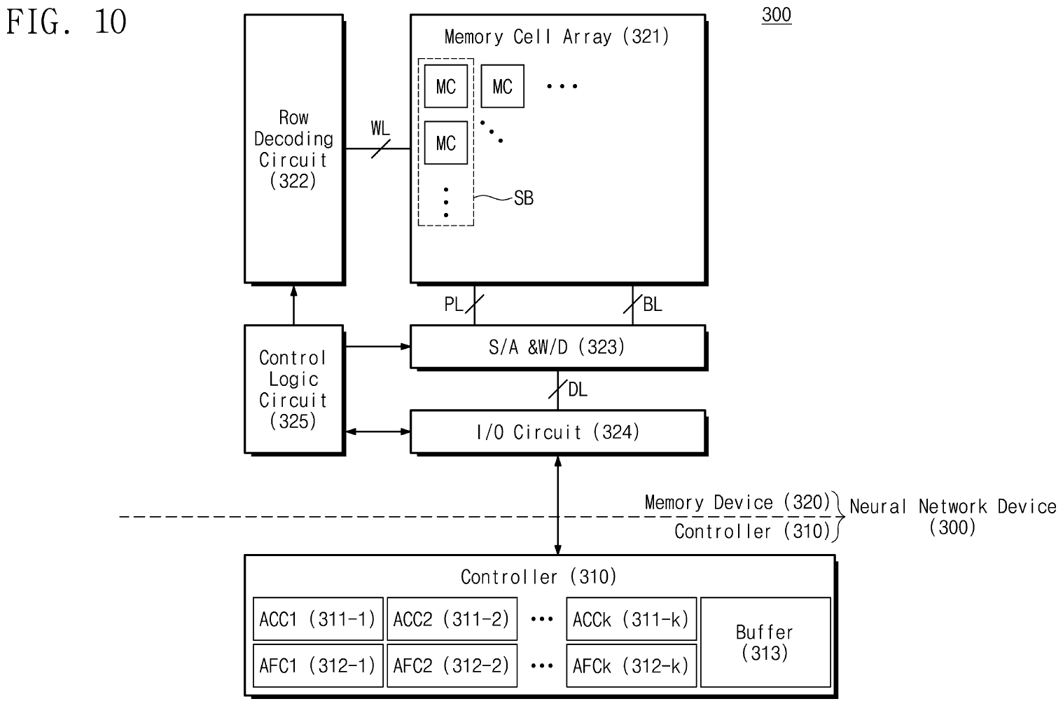

FIG. 10 is a block diagram of a neural network device, according to some embodiments of the present disclosure. Referring to FIG. 10, a neural network device 300 may include a controller 310 and a memory device 320. The neural network device 300 is somewhat similar to the neural network device 100 of FIG. 3, and thus redundant description will be omitted.

The controller 310 may re-write weights into the plurality of memory cells MC. For example, after weights of a layer stored in a sub-block SB are read out and then multiplication calculations of the weights and input data are performed, the controller 310 may re-write the weights into the sub-block SB.

The controller 310 may include a plurality of accumulators 311-1 to 311-k, a plurality of activation function circuits 312-1 to 312-k, and a buffer 313. The buffer 313 may store weights. For example, the buffer 313 may store weights for re-writing the plurality of memory cells MC.

In some embodiments, the buffer 313 may store weights received from an external device (e.g., the main processor 11 of FIG. 1, the buffer memory device 12 of FIG. 1, or other devices). The weights may be identical to or different from the weights stored in the plurality of memory cells MC.

The controller 310 may re-write weights in some of the plurality of memory cells MC. In some embodiments, the controller 310 may re-write weights into the memory cells of the sub-block SB, from which the weights are read out, from among the plurality of memory cells MC. For example, after the memory cells of the sub-block SB, in which the weights of the first layer are stored, from among the plurality of memory cells MC are read out and multiplication calculations of the weights and input data are performed, the controller 310 may re-write the weights of the first layer in the read memory cells.

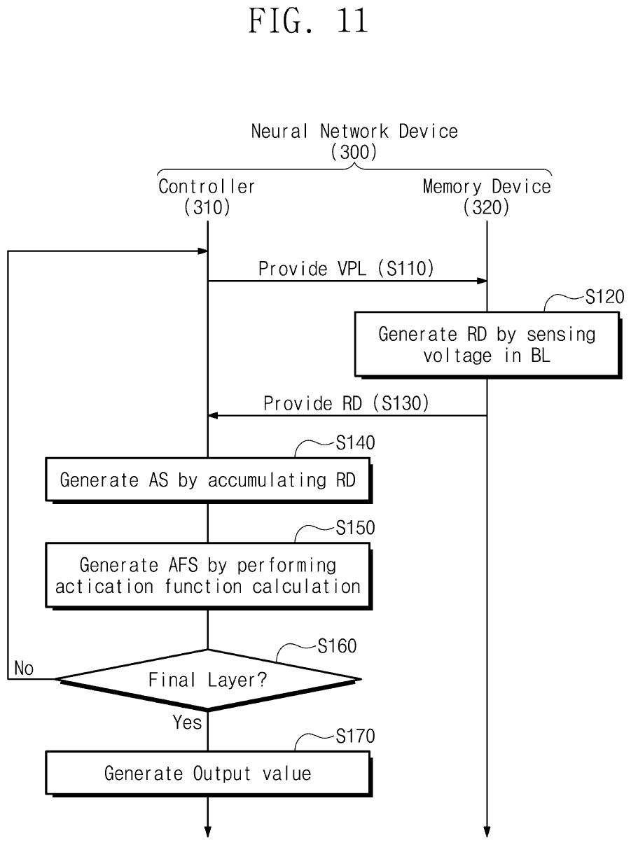

FIG. 11 is a flowchart for describing a method of operating a neural network device, according to some embodiments of the present disclosure. Referring to FIG. 11, the neural network device 300 may include the controller 310 and the memory device 320.

In operation S110, the controller 310 may provide the plate voltage VPL to the memory device 320. For example, the controller 310 may provide the memory device 320 with the plate voltage VPL corresponding to input data or activation signals. In some embodiments, the controller 310 may simultaneously provide the plate voltage VPL to the memory cells of the memory device 320 connected to plate lines. The controller 310 may perform neural network operations simultaneously by simultaneously providing the plate voltage VPL to the memory cells.

In some embodiments, the controller 310 may provide the plate voltage VPL to ferroelectric capacitor sets connected to the plate lines. Each of the ferroelectric capacitor sets may include a plurality of ferroelectric capacitors connected to a single plate line.

In operation S120, the memory device 320 may generate the read data RD by sensing a voltage within the bit line BL. For example, the memory device 320 may perform multiplication calculations on data (e.g., input data or activation signals) and weights based on the plate voltage VPL and the weights stored in the memory device 320.

In some embodiments, the memory cells of the memory device 320 may store weights for neural network operations. For example, the memory cells of the memory device 320 may store weights of a plurality of layers (e.g., a first layer, a second layer, or the like).

In some embodiments, the memory cells of the memory device 320 may receive a plate voltage (corresponding to input data or activation signals) through a plurality of plate lines, each of which is connected to at least two ferroelectric capacitors. The multiplication calculations of the input data (or activation signals) and the weight may be performed based on the weight, which are stored in the memory cell, and a voltage level of the plate voltage. There may be a voltage change corresponding to the result of multiplying the input data (or activation signals) and the weight on the bit line BL connected to the memory cell.

In some embodiments, a sense amplifier/write driver of the memory device 320 may sense a voltage change of the bit line BL, and may read out the result of a multiplication calculation of data (input data or activation signals) and weights, which are stored in the memory cells, as the read data RD based on the sensed voltage change. Accordingly, the memory device 320 may generate the read data RD by sensing a voltage within the bit line BL.

In some embodiments, the weights stored in the memory device 320 may have a plurality of (i.e., at least two) levels. For example, when the memory device 320 includes ‘n’ ferroelectric capacitor sets, the weight may have the maximum of (n+1) levels.

In operation S130, the memory device 320 may provide the read data RD to the controller 310. For example, the memory device 320 may provide an accumulator of a controller corresponding to the bit line BL with the read data RD read from the ferroelectric capacitor sets connected to the bit line BL. The read data RD may correspond to the result of multiplying input data (or activation signals) and a weight.

In operation S140, the controller 310 may generate the accumulation signal AS by accumulating the read data RD. For example, the controller 310 may receive the pieces of read data RD from a plurality of ferroelectric capacitor sets of the memory device 320 connected to the bit line BL, and may generate the accumulation signal AS by performing an accumulation operation on the pieces of read data RD.

In operation S150, the controller 310 may generate an activation signal AFS by performing an activation function calculation. For example, the controller 310 may generate an activation signal by performing an activation function calculation of the accumulation signal AS.

The activation function may be at least one of a sigmoid function, a tangent hyperbolic (tanh) function, a rectified linear unit (ReLU) function, a leaky ReLU function, an exponential linear unit (ELU) function, a softmax function, a Swish function, and a Gaussian error linear unit (GELU) function.

In operation S160, the controller 310 may determine whether operations performed in operations S110 to S150 are part of the calculation on the last layer of a neural network. In some embodiments, when the controller 310 determines that operations performed in operations S110 to S150 are not part of the calculation on the last layer of the neural network, the neural network device 300 may repeat operations S110 to S150 on the next layer.

In operation S170, the controller 310 may generate an output value. For example, when the controller 310 determines that operations performed in operations S110 to S150 are part of the calculation for the last layer of the neural network, the controller 310 may generate an output value based on the activation signal AFS. The output value may indicate the result of learning or inference of the data input to the neural network.

In some embodiments, the controller 310 may return the output value as the output value of the neural network operation to an external device (e.g., the main processor 11 of FIG. 1).

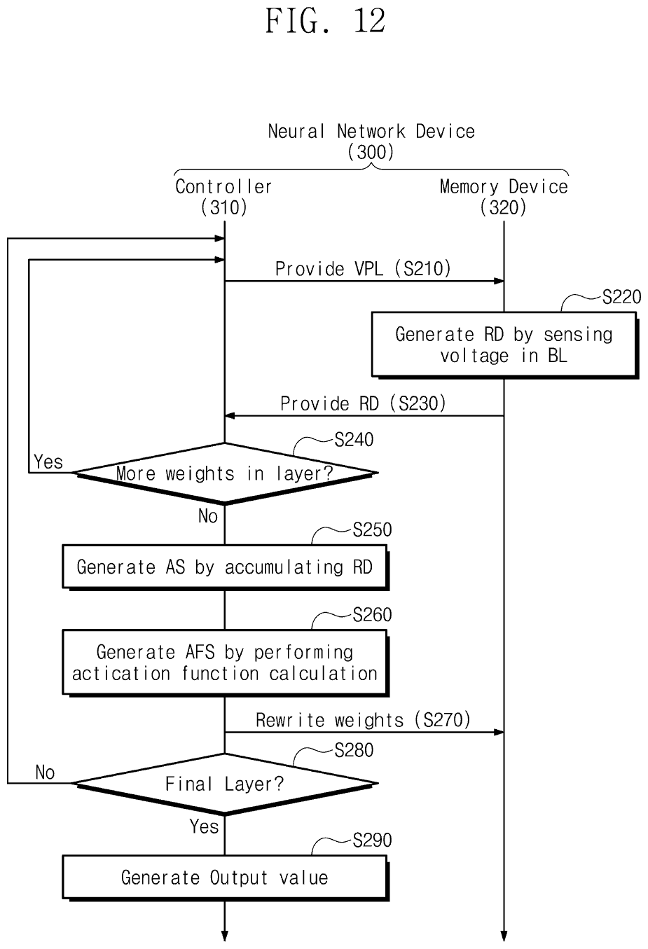

FIG. 12 is a flowchart for describing a method of operating a neural network device, according to some embodiments of the present disclosure. Referring to FIG. 12, the neural network device 300 may include the controller 310 and the memory device 320. The flowchart of FIG. 12 is partially similar to the flowchart of FIG. 11, and thus redundant descriptions will be omitted.

In operation S210, the controller 310 may provide the plate voltage VPL to the memory device 320. For example, the controller 310 may provide the memory device 320 with the plate voltage VPL corresponding to input data or activation signals.

In some embodiments, the controller 310 may simultaneously provide the plate voltage VPL to ferroelectric capacitor set of one unit (e.g., a sub-block) storing weights of one layer. For example, the controller 310 may simultaneously provide the plate voltage VPL to ferroelectric capacitors located in one stage (e.g., a first stage) of a sub-block storing the weights of one layer.

In operation S220, the memory device 320 may generate the read data RD by sensing a voltage within the bit line BL. For example, the memory device 320 may perform multiplication calculations on data (e.g., input data or activation signals) and weights based on the plate voltage VPL and the weights stored in the memory device 320.

In some embodiments, the sub-blocks of the memory device 320 may store weights for neural network operations. For example, the sub-blocks of the memory device 320 may store weights of a plurality of layers (e.g., a first layer, a second layer, or the like).

In some embodiments, the multiplication calculations of input data (or activation signals) and a weight may be performed based on weights, which are stored in one sub-block, and a voltage level of the plate voltage. There may be a voltage change corresponding to the result of multiplying the input data (or activation signals) and the weight on the bit line BL connected to the memory cell.

In some embodiments, a sense amplifier/write driver of the memory device 320 may sense a voltage change of the bit line BL, and may read out the result of a multiplication calculation of data (input data or activation signals) and weights, which are stored in the sub-block, as the read data RD based on the sensed voltage change. Accordingly, the memory device 320 may generate the read data RD by sensing a voltage within the bit line BL.

In operation S230, the memory device 320 may provide the read data RD to the controller 310. For example, the memory device 320 may provide an accumulator of a controller corresponding to the bit line BL with the read data RD read from the sub-block connected to the bit line BL. The read data RD may correspond to the result of multiplying input data (or activation signals) and a weight.

In operation S240, the controller 310 may determine whether there are more weights, on which a multiplication calculation is not performed, in a layer. For example, when weights of one layer are divided and stored in a plurality of stages of a sub-block, the controller 310 may determine whether operations of operations S210 to S230 are performed on all stages. For example, when the memory device 320 divides weights of the first layer into a first portion and a second portion and then stores the first portion and the second portion in ferroelectric capacitor sets located in two stages of a sub-block, the controller 310 may determine whether operations of operations S210 to S230 are performed on all of the weights of the first layer.

In some embodiments, when the controller 310 determines that there are more weights, on which a multiplication calculation is not performed, in a layer, the neural network device 300 may repeat operations S210 to S230 on the next stage of the sub-block.

In operation S250, the controller 310 may generate the accumulation signal AS by accumulating the read data RD. For example, when the controller 310 determines that there are no more weights, on which a multiplication calculation is not performed, in a layer, the controller 310 may generate the accumulation signal AS by accumulating the read data RD.

In some embodiments, the controller 310 may receive the pieces of read data RD from a plurality of ferroelectric capacitor sets of a sub-block of the memory device 320 connected to the bit line BL, and may generate the accumulation signal AS by performing an accumulation operation on the pieces of read data RD.

In operation S260, the controller 310 may generate the activation signal AFS by performing an activation function calculation. For example, the controller 310 may generate an activation signal by performing an activation function calculation of the accumulation signal AS.

In operation S270, the controller 310 may re-write weights in the memory device 320. For example, after weights of a layer stored in a sub-block are read out and then multiplication calculations of weights and input data are performed, the controller 310 may re-write the weights into the sub-block.

In some embodiments, the controller 310 may store weights identical to weights, which are stored in the memory device 320, in a buffer of the controller 310. The controller 310 may re-write weights in the sub-block of the memory device 320, on which operations S210 to S260 are performed, based on the weights stored in the buffer.

In operation S280, the controller 310 may determine whether operations performed in operations S210 to S270 are part of the calculation on the last layer of a neural network. In some embodiments, when the controller 310 determines that operations performed in operations S210 to S270 are not part of the calculation on the last layer of the neural network, the neural network device 300 may repeat operations S210 to S270 on the next layer.

Although operations S270 and S280 are illustrated as being performed sequentially, the scope of the present disclosure is not limited thereto. Operations S270 and S280 may be performed at the same time.

In operation S280, the controller 310 may generate an output value. For example, when the controller 310 determines that operations performed in operations S210 to S260 are part of the calculation for the last layer of the neural network, the controller 310 may generate an output value based on an activation signal AFS.

In some embodiments, the controller 310 may return the output value as the output value of the neural network operation to an external device (e.g., the main processor 11 of FIG. 1).

FIG. 13A is a perspective view for describing a plate line, according to some embodiments of the present disclosure. Referring to FIG. 13A, the first plate line PL1 may be formed by merging a first sub-plate line SPL1 and a second sub-plate line SPL2. For example, the first sub-plate line SPL1 may be connected to the first ferroelectric capacitor FC1 of FIG. 5 in a second direction D2 (e.g., to a first plate of the first ferroelectric capacitor FC1), and the second sub-plate line SPL2 may be connected to the second ferroelectric capacitor FC2 of FIG. 5 in the second direction D2 (e.g., to a first plate of the second ferroelectric capacitor FC2).

The first sub-plate line SPL1 may be placed to be space apart from the second sub-plate line SPL2 in the first direction D1 (perpendicular to the second direction D2). Furthermore, the first sub-plate line SPL1 and the second sub-plate line SPL2 may extend in the second direction D2 and may be arranged parallel to each other.

In some embodiments, the first sub-plate line SPL1 and the second sub-plate line SPL2 may be merged with each other to form the first plate line PL1. For example, a metal pad MP may be placed between the first sub-plate line SPL1 and the second sub-plate line SPL2. The metal pad MP may contact the first sub-plate line SPL1 and the second sub-plate line SPL2 in the second direction D2 and a third direction D3, such that the first sub-plate line SPL1 and the second sub-plate line SPL2 are directly electrically connected through the metal pad MP. The metal pad MP may be implemented with a conductive metal such as copper or iron. The first sub-plate line SPL1 and the second sub-plate line SPL2 may be electrically connected to each other through the metal pad MP, and may be merged with each other to form the first plate line PL1.

The first sub-plate line SPL1 may contact one side of a contact CM, which extends in the first direction D1, in the second direction D2, and the third direction D3. The other side of the contact CM may be connected to the sense amplifier/write driver 123 of FIG. 3. The contact CM may be implemented with a conductive metal such as copper or iron.

FIG. 13B is a perspective view for describing a plate line, according to some embodiments of the present disclosure. Referring to FIG. 13B, the first plate line PL1 may be formed by merging a plurality of sub-plate lines SPL1 to SPLn. For example, the plurality of sub-plate lines SPL1 to SPLn, which extend in the second direction D2 and are placed parallel to each other, may be electrically connected to each other through the contact CM extending in the first direction D1 (perpendicular to the second direction D2) to form the first plate line PL1. The plurality of sub-plate lines SPL1 to SPLn may be placed to be spaced apart from each other in the first direction D1.

In some embodiments, the contact CM extends in the first direction D1 and one side thereof may be connected to the sense amplifier/write driver 123 of FIG. 3. The contact CM may sequentially penetrate the plurality of sub-plate lines SPL1 to SPLn in the first direction D1. The contact CM may be implemented with a conductive metal such as copper or iron.

The above description refers to detailed embodiments for carrying out the present disclosure. The present disclosure may include embodiments in which a design is changed simply or which are easily changed, as well as the embodiments described above. In addition, technologies that are easily changed and implemented by using the above embodiments may be implemented based on the teachings of the present disclosure. While the present disclosure has been described with reference to embodiments described above, it will be apparent to those of ordinary skill in the art that various changes and modifications may be made thereto without departing from the spirit and scope of the present invention as set forth in the following claims.

According to an embodiment of the present disclosure, a memory-based neural network device and an operating method thereof are provided.

Moreover, a memory-based neural network device, which may provide more stable storage and may perform more diverse and faster neural network operations as a plurality of ferroelectric capacitors store weight data having multiple levels as sets, is provided.

What is claimed is:

1. A neural network device comprising:
a first memory cell connected to a first word line, a first bit line, and a first plate line; and
a controller configured to provide a first plate voltage to the first memory cell through the first plate line,
wherein the first memory cell includes:
a transistor controlled by the first word line and connected to the first bit line; and
a first ferroelectric capacitor set including a plurality of ferroelectric capacitors connected in parallel between the transistor and the first plate line.

2. The neural network device of claim 1, wherein the plurality of ferroelectric capacitors store a piece of data.

3. The neural network device of claim 1, wherein the first plate line is formed by merging a plurality of sub-plate lines, which are respectively connected to the plurality of ferroelectric capacitors, at a first node, and
wherein the plurality of ferroelectric capacitors simultaneously receive the first plate voltage from the controller through the first plate line.

4. The neural network device of claim 1, wherein the first memory cell is further connected to second to N-th plate lines,
wherein the controller is further configured to provide second to N-th plate voltages to the first memory cell through the second to N-th plate lines, respectively,
wherein the first memory cell further includes second to N-th ferroelectric capacitor sets respectively corresponding to the second to N-th plate lines, and
wherein ‘N’ is an integer greater than 2.

5. The neural network device of claim 4, wherein the first memory cell is configured to store a first weight, and
wherein the first weight has one of (N+1) levels.

6. The neural network device of claim 4, wherein the first memory cell stores first to K-th weights,
wherein each of the first to K-th weights have one of at least two levels, and
wherein ‘K’ is an integer greater than 1 and less than or equal to ‘N’.

7. The neural network device of claim 1, further comprising:
second to M-th memory cells connected between the first bit line and the first plate line,
wherein the second to M-th memory cells receive the first plate voltage from the controller through the first plate line, and
wherein ‘M’ is an integer greater than 2.

8. The neural network device of claim 7, further comprising:
a sense amplifier and write driver connected to the first to M-th memory cells through the first bit line,
wherein the first to M-th memory cells are configured to store first to M-th weights, respectively, and
wherein the sense amplifier and write driver is configured to:
sense a first voltage change of the first bit line and read out results of first to M-th multiplication calculations of the first plate voltage and the first to M-th weights; and
generate first to M-th read data based on the results of the first to M-th multiplication calculations.

9. The neural network device of claim 8, wherein the controller further includes:
a first accumulator configured to receive the first to M-th read data from the sense amplifier and write driver, and to generate a first accumulation signal by performing an accumulation operation of the first to M-th read data; and
a first activation function circuit configured to receive the first accumulation signal from the first accumulator and to generate a first activation signal by performing an activation function calculation of the first accumulation signal.

10. The neural network device of claim 9, wherein the controller is configured to:
determine whether the first to M-th weights are weights of a last layer of a neural network;
generate an output signal based on the first activation signal in response to determining that the first to M-th weights are the weights of the last layer; and
generate the first plate voltage based on the first activation signal in response to determining that the first to M-th weights are not weights of the last layer.

11. The neural network device of claim 7, further comprising:
(M+1)-th to 2M-th memory cells connected between a second bit line and a second plate line and configured to receive a second plate voltage through the second plate line,
wherein the first to M-th memory cells are configured to store first to M-th weights of a first layer, respectively,
wherein the (M+1)-th to 2M-th memory cells are configured to store (M+1)-th to 2M-th weights of a second layer, respectively,
wherein the controller further includes:
a buffer configured to store the first to 2M-th weights, and
wherein the controller is configured to:
read out a first voltage change of the first bit line by providing the first plate voltage to the first to M-th memory cells, and generate a first activation signal based on the first voltage change;
re-write the first to M-th weights in the first to M-th memory cells;
read out a second voltage change of the second bit line by providing the second plate voltage to the (M+1)-th to 2M-th memory cells, and generate a second activation signal based on the second voltage change; and
re-write the (M+1)-th to 2M-th weights in the (M+1)-th to 2M-th memory cells.

12. A method of operating a neural network device including a controller and a memory device, the method comprising:
simultaneously providing, by the controller, a first plate voltage to ferroelectric capacitor sets of the memory device, wherein the ferroelectric capacitor sets include a plurality of ferroelectric capacitors connected to a first plate line and configured to respectively store weights of a first layer;
generating, by the memory device, read data by sensing a voltage of bit lines connected to the ferroelectric capacitor sets;
providing, by the memory device, the read data to the controller;
generating, by the controller, accumulation signals by accumulating the read data;
generating, by the controller, activation signals by performing activation function calculations of the accumulation signals;
determining, by the controller, whether the first layer is a last layer of a neural network;
generating, by the controller, a second plate voltage based on the activation signals in response to determining that the first layer is not the last layer; and
simultaneously providing, by the controller, the second plate voltage to the ferroelectric capacitor sets of the memory device.

13. The method of claim 12, wherein the determining, by the controller, of whether the first layer is the last layer of the neural network further includes:
generating, by the controller, an output value based on the activation signals in response to determining that the first layer is the last layer.

14. The method of claim 12, wherein the plurality of ferroelectric capacitors are respectively connected to a plurality of sub-plate lines, and
wherein the first plate line is formed by merging the plurality of sub-plate lines.

15. The method of claim 12, wherein the memory device is further connected to a second plate line, and
wherein the plurality of ferroelectric capacitors are placed to be divided into a first stage, which stores a first portion of the weights and is connected to the first plate line, and a second stage, which stores a second portion of the weights and is connected to the second plate line.

16. The method of claim 15, wherein the generating, by the memory device, of the read data by sensing the voltage of the bit lines connected to the ferroelectric capacitor sets includes:
generating, by the memory device, first read data by sensing the voltage of the bit lines connected to the ferroelectric capacitor sets located in the first stage, and
wherein the providing, by the memory device, of the read data to the controller includes:
providing, by the memory device, the first read data to the controller,
further comprising:
determining, by the controller, whether there are some of the weights for which read data is not generated; and
providing, by the controller, the second plate voltage to the ferroelectric capacitor sets located in the second stage in response to determining that there are some of the weights for which read data is not generated.

17. The method of claim 16, wherein the generating, by the controller, of the activation signals by performing the activation function calculations of the accumulation signals further includes:
re-writing, by the controller, the weights to the plurality of ferroelectric capacitors.

18. The method of claim 17, wherein the controller further includes a buffer, and
wherein the re-writing, by the controller, of the weights to the plurality of ferroelectric capacitors includes:
re-writing, by the controller, the weights to the plurality of ferroelectric capacitors based on weights stored in the buffer.

19. The method of claim 12, wherein the read data corresponds to a result of multiplication calculations of input data of the neural network corresponding to the first plate voltage and weights.

20. The method of claim 13, further comprising:
returning, by the controller, the output value to an external device.
